(19) United States
(12) Patent Application Publication
(10) Pub. No.: US 2009/0020794 A1
(43) Pub. Date: Jan. 22, 2009

(54) Image Sensor and Method of Manufacturing the Same

(76) Inventor: Min Hyung Lee, Cheongju-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 12/144,768

(22) Filed: Jun. 24, 2008

(30) Foreign Application Priority Data
Jul. 19, 2007 (KR) 10-2007-0072350

(51) Int. Cl. H01L 31/112; H01L 21/28

(52) U.S. Cl. 257/292; 438/69; 257/E31.073; 257/E21.158

(57) ABSTRACT

Provided are an image sensor and a method of manufacturing the same. The image sensor can be vertically arranged image sensor where the photodiode is provided above the circuitry on the substrate. The photodiode can be formed on a lower electrode provided electrically connected to a CMOS circuit on a substrate. The photodiode can have a PIN or PI photodiode structure including an intrinsic layer on the lower electrode and a conductive type layer on the intrinsic layer. A salicide layer can be disposed on the intrinsic layer, and the conductive type conduction layer can be disposed on the salicide layer. The intrinsic layer can be formed to create a light condensing portion, providing a convex-shaped upper surface.

### CROSS-REFERENCE TO RELATED APPLICATION

The present application claims the benefit under 35 U.S.C. §119 of Korean Patent Application No. 10-2007-0072350, filed Jul. 19, 2007, which is hereby incorporated by reference in its entirety.

### BACKGROUND

An image sensor is a semiconductor device that converts an optical image to an electric signal. An image sensor can be generally classified as a charge coupled device (CCD) or a complementary metal oxide semiconductor (CMOS) image sensor (CIS).

The CIS includes a photodiode and a MOS transistor in a unit pixel. The CIS sequentially detects electric signals of unit pixels in a switching manner to realize an image.

A typical CIS includes a photodiode region and a transistor horizontally arranged on a semiconductor substrate for each unit pixel. A light signal is converted into an electrical signal in the photodiode region, and the transistor processes the electric signal.

The photodiode of such a typical CIS is horizontally adjacent to the transistor on the substrate. Therefore, an additional portion of the substrate for each unit pixel is required for forming the photodiode region.

### BRIEF SUMMARY

Embodiments of the present invention provide an image sensor in which a transistor circuit and a photodiode can be vertically integrated and a method of manufacturing the image sensor.

In one embodiment, an image sensor comprises: a lower electrode on a metal interconnection connecting to a CMOS circuit on a semiconductor substrate, the metal interconnection formed through an interlayer dielectric; an intrinsic layer on the interlayer dielectric and the lower electrode; a salicide layer on the intrinsic layer; a conductive type conduction layer on the salicide layer; and an upper electrode on the conductive type conduction layer. In a further embodiment, the intrinsic layer can have a convex-shaped top surface portion.

In another embodiment, a method of manufacturing an image sensor comprises: forming a transistor circuit on a semiconductor substrate; forming an interlayer dielectric and a metal interconnection on the semiconductor substrate, the metal interconnection connected to the transistor circuit; forming a lower electrode on the metal interconnection; forming an intrinsic layer on the interlayer dielectric and the lower electrode; forming a salicide layer on the intrinsic layer; forming a conductive type conduction layer on the salicide layer; and forming an upper electrode on the conductive type conduction layer.

The details of one or more embodiments are set forth in the accompanying drawings and the description below. Other features will be apparent from the description and drawings, and from the claims.

### BRIEF DESCRIPTION OF THE DRAWINGS

FIGS. 1 to 10 are cross-sectional views illustrating a process of manufacturing an image sensor according to an embodiment of the present invention.

### DETAILED DESCRIPTION

Hereinafter, an image sensor and a method of manufacturing the same will be described in detail with reference to the accompanying drawings.

When the terms “on” or “over” are used herein, when referring to layers, regions, patterns, or structures, it is understood that the layer, region, pattern or structure can be directly on another layer or structure, or intervening layers, regions, patterns, or structures may also be present. When the terms “under” or “below” are used herein, when referring to layers, regions, patterns, or structures, it is understood that the layer, region, pattern or structure can be directly under the other layer or structure, or intervening layers, regions, patterns, or structures may also be present.

FIG. 10 is a cross-sectional view of an image sensor according to an embodiment of the present invention.

Referring to FIG. 10, a semiconductor substrate 10 can be provided with a complementary metal oxide semiconductor (CMOS) circuit (indicated by transistor 11).

The CMOS circuit can be provided for each unit pixel. In one embodiment, the CMOS circuit can be a four transistor type (4-Tr type) circuit. For example, the 4-Tr type circuit includes a transfer transistor, a reset transistor, a drive transistor, and a select transistor. The transfer transistor is connected to the photodiode to convert a received photo charge into an electric signal. According to an embodiment, the transistor 11 can be a transfer transistor, and the source region of the transfer transistor can be electrically connected to the photodiode disposed above the CMOS circuit through a metal interconnection as shown in FIG. 10. Of course other CMOS circuit designs can be used, such as, for example, a 3-Tr type and 5-Tr type circuit.

An interlayer dielectric 20 including a metal interconnection 31 and a pad 32 is disposed on a semiconductor substrate 10. The interlayer dielectric 20 can include a plurality of layers, and the metal interconnection 31 can be provided in plurality. Certain ones of the metal interconnections 31 can be used to electrically connect a photodiode to the CMOS circuit.

A lower electrode 41 can be disposed on a top surface of the metal interconnection 31. In certain embodiments, the lower electrode 41 can be formed of a metal such as chromium (Cr), titanium (Ti), titanium tungsten (TiW), and tantalum (Ta).

The lower electrode 41 can be disposed on the metal interconnection 31 and the interlayer dielectric 20 to cover the metal interconnection 31. A lower electrode 41 can be disposed on an upper side of the metal interconnection 31 provided for each unit pixel. The lower electrodes 41 can be separated from each other for each unit pixel.

A photodiode 80 can be disposed on the interlayer dielectric 20 and the lower electrode 41.

The photodiode 80 can include an intrinsic layer 50 and a conductive type conduction layer 70. In one embodiment, the intrinsic layer 50 can include an intrinsic amorphous silicon layer, and the conductive type conduction layer 70 can include a p-type amorphous silicon layer.

According to certain embodiments, the intrinsic layer 50 can have a thickness in the range of about 2000 521 to about 20,000 Å, and the conductive type conduction layer 70 can have a thickness in the range of about 50 Å to about 500 Å.

The intrinsic layer 50 can include a convex-shaped light condensing portion 51 at a surface of the intrinsic layer 50. Accordingly, the conductive type conduction layer 70 disposed on the intrinsic layer 50 can also have a hemispherical shape following the shape of the light condensing portion 51.

Thus, a surface of the photodiode 80 can have a convex shape similar to that of a microlens to improve light condensing efficiency of the photodiode 80.

A salicide layer 65 can be provided between the intrinsic layer 50 and the conductive type conduction layer 70. In one embodiment, the salicide layer 65 can be formed of Cr or molybdenum (Mo). In a specific embodiment, the salicide layer 65 can have a thickness in the range of about 50 Å to about 500 Å.

The salicide layer 65 can be disposed on the intrinsic layer 50 to remove a dangling bond generated in the intrinsic layer 50.

In a further embodiment, an upper electrode 90 can be disposed on the photodiode 80.

The upper electrode 90 can include a transparent electrode having excellent light transmittance and high conductivity. For example, the upper electrode 90 can be formed of indium tin oxide (ITO), cadmium tin oxide (CTO), or zinc oxide (ZnO₂).

As described above, the CMOS circuit (represented by transistor 11) and the photodiode 80 can be vertically integrated to increase a fill factor of an image sensor.

In addition, the surface of the photodiode 80 can have a convex shape such as that of a microlens to improve the light condensing efficiency of the image sensor.

A method of manufacturing an image sensor according to an embodiment will now be described with reference to the accompanying drawings.

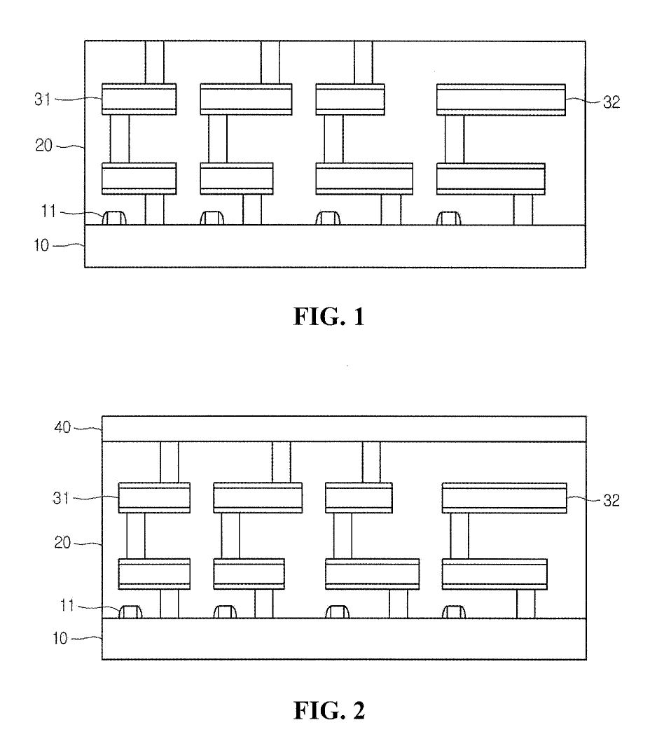

Referring to FIG. 1, an interlayer dielectric 20 including a metal interconnection 31 can be formed on a semiconductor substrate 10 including a CMOS circuit (represented by transistor 11).

Although not shown, a device isolation layer can be formed in the semiconductor substrate 10 to define an active region and a field region.

The CMOS circuit 11 can be formed in a unit pixel formed in the active region. In one embodiment using a 4-Tr type circuit, the CMOS circuit can include a transfer transistor, a reset transistor, a drive transistor, and a select transistor. The transfer transistor is connected to a photodiode formed above the CMOS circuit to convert a received photo charge into an electric signal.

The interlayer dielectric 20 and metal interconnections 31 are formed on the semiconductor substrate 10 including the CMOS circuit to connect the CMOS circuit to power lines and signal lines according to any suitable design.

The interlayer dielectric 20 can include a plurality of layers. According to many embodiments, the interlayer dielectric 20 can include an oxide layer.

The metal interconnection 31 passes through the interlayer dielectric 20 and can be formed in plurality. In an embodiment, the metal interconnection 31 can be formed of one or more conductive materials, including a metal, an alloy, or a salicide. In a specific embodiment, the metal interconnection 31 can include aluminum (Al), copper (Cu), cobalt (Co), or tungsten (W).

A pad 32 can also be formed when the metal interconnection 31 is formed. In one embodiment, the metal interconnection 31 includes a final via. The methods and layers used for forming the interlayer dielectric 20, metal interconnections 31, and pad 32 include any suitable methods and layers known in the art.

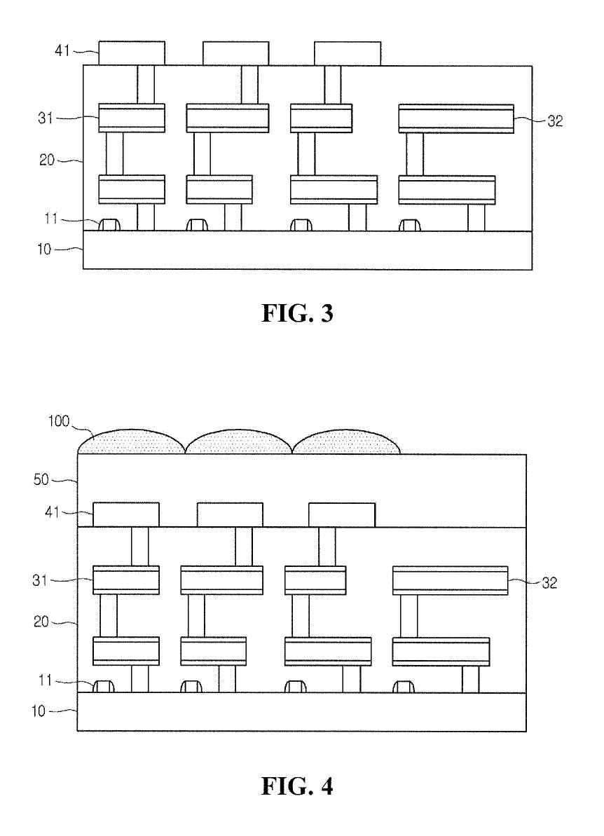

Referring to FIGS. 2 and 3, a lower electrode 41 can be formed on the interlayer dielectric 20 including the metal interconnection 31.

To form the lower electrode 41 on the metal interconnection 31 formed for each unit pixel, a metal layer 40 can be formed on the interlayer dielectric 20, and then patterned though photolithography and etching processes. The metal layer 40 can be, for example, a metal such as Cr, Ti, TiW, or Ta. In a specific embodiment, the metal layer 40 can be a chrome layer (Cr).

The metal interconnection 31 and lower electrode 41 can be formed for each unit pixel to connect the CMOS circuit 11 to a photodiode 80, which will be described below.

Since the metal interconnection 31 and the lower electrode 41 are formed for each unit pixel, the photodiode 80 can be electrically patterned for each unit pixel. That is, the photodiode 80 does not require separate isolation for each unit pixel, and can be effectively used for each unit pixel according to the patterned lower electrode 41.

The photodiode 80 can be formed on the interlayer dielectric 20 including the metal interconnection 31 and the lower electrode 41 such that the photodiode 80 is electrically connected to each metal interconnection 31.

The photodiode 80 formed on the interlayer dielectric 20 receives light incident from the outside to electrically convert the incident light into an electric signal and store the converted electric signal.

The performance of a photodiode depends on its efficiency of converting incident light into electric charges and its charge capacitance. A typical photodiode generates and stores electric charges in a depletion region created by hetero junctions provided in the form of P—N, N—P, N—P—N, or P—N—P .

In contrast, an IP (or PIN) diode utilizes its stacked structure, in which an intrinsic layer is sandwiched between a p-type amorphous silicon layer and metal (or an n-type amorphous silicon layer), to provide a depletion region. The entire intrinsic amorphous silicon layer formed between the p-type amorphous silicon layer and the metal (or n-type amorphous silicon layer) is a depletion region. Therefore, electric charges can be advantageously generated and stored.

According to embodiments of the present invention, a PIN diode can be used as the photodiode. The PIN diode can have a structure such as P—I—N or N—I—P. The PIN diode structure can also utilize an I—P structure.

The PIN diode having an I—P structure will be described in reference to the figures. The intrinsic layer can be an intrinsic amorphous silicon layer, and the conductive type conduction layer can be a p-type amorphous silicon layer. However, embodiments are not limited thereto

Referring to FIG. 4, an intrinsic layer 50 can be formed on the interlayer dielectric 20. The intrinsic layer 50 can serve as an I-layer of the IP diode.

In one embodiment, an n-type conductive type conduction layer can be formed before forming the intrinsic layer 50 to provide an N—I—P diode structure. The n-type conductive type conduction layer can be formed according to any suitable method known in the art.

As described above, the intrinsic layer 50 can be formed of intrinsic amorphous silicon. The intrinsic layer 50 can be formed using a chemical vapor deposition (CVD) method such as plasma enhanced chemical vapor deposition (PECVD). For example, the intrinsic layer 50 can be formed of the intrinsic amorphous silicon by performing PECVD using silane (SiH₄) gas.

Here, a thickness of the intrinsic layer 50 can be about ten times to about one thousand times greater than that of the conductive type conduction layer 70. The intrinsic layer 50 is formed thickly because the depletion region of the PIN diode increases as the thickness of the intrinsic layer 50 increases. Therefore, many photoelectrons can be advantageously generated and stored. In certain embodiments, the intrinsic layer 50 can have a thickness between about 2000 Å and about 20,000 Å.

Then, in one embodiment, a photoresist pattern 100 can be formed on the intrinsic layer 50.

The photoresist pattern 100 can be formed by coating a photoresist layer on the intrinsic layer 50 and patterning the photoresist according to each unit pixel. The photoresist pattern 100 can be formed having a hemispherical shape by performing a reflow process.

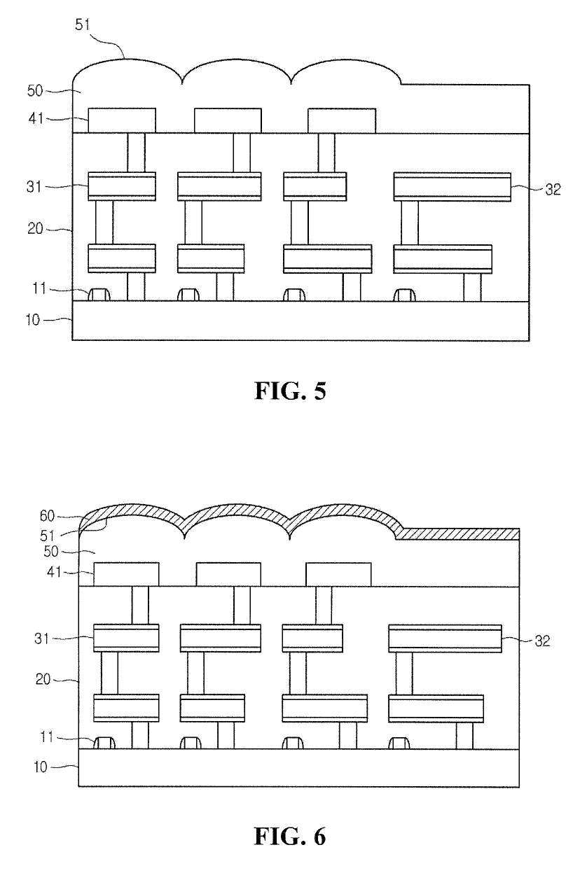

Referring to FIG. 5, a convex-shaped light condensing portion 51 can be formed on a surface of the intrinsic layer 50 by etching the intrinsic layer 50 using the photoresist pattern 100 as an etch mask.

Because the hemisphere-shaped light condensing portion 51 is formed on a surface of the intrinsic layer 50, the conductive type conduction layer 70 and an upper electrode 90 formed on the intrinsic layer 50 can also have a convex or hemispherical shape.

The light condensing portion 51 having the convex hemispherical shape for each unit pixel can be formed on the intrinsic layer 50 to aid in condensing light incident onto the photodiode. The light condensed by the light condensing portion 51 is converted into electrons, and the converted electrons are transmitted to the CMOS circuit 11 through the lower electrode 41 and the metal interconnection 31. Since the light incident onto the photodiode is condensed by the light condensing portion 51, the light can be inhibited from passing between adjacent lower electrodes 41. Therefore, cross talk and noise can be inhibited from occurring.

A dry etching or a wet etching process can be performed to form the light condensing portion 51 on the surface of the intrinsic layer 50. However, when the intrinsic layer 50 is etched, a surface bond of a material forming the intrinsic layer 50 may be damaged due to the etching process. That is, the etching process can generate a dangling bond.

The dangling bond creates a state where charges may be easily generated due to a thermal aspect—even without input of incident lights. Thus, if there exists a plurality of dangling bonds, a dark current occurs. Therefore, the image sensor shows an abnormal state by acting as if there are inputs of the incident lights even in a dark state without any light. By forming a salicide layer 65 on the intrinsic layer 50, the dangling bonds and dark current defects can be inhibited.

Referring to FIG. 6, a metal layer 60 for forming a salicide layer can be deposited on the intrinsic layer 50. In certain embodiments, the metal layer 60 can be formed of Cr or Mo using a physical vapor deposition (PVD) method. In a specific embodiment, the metal layer 60 is formed of Cr.

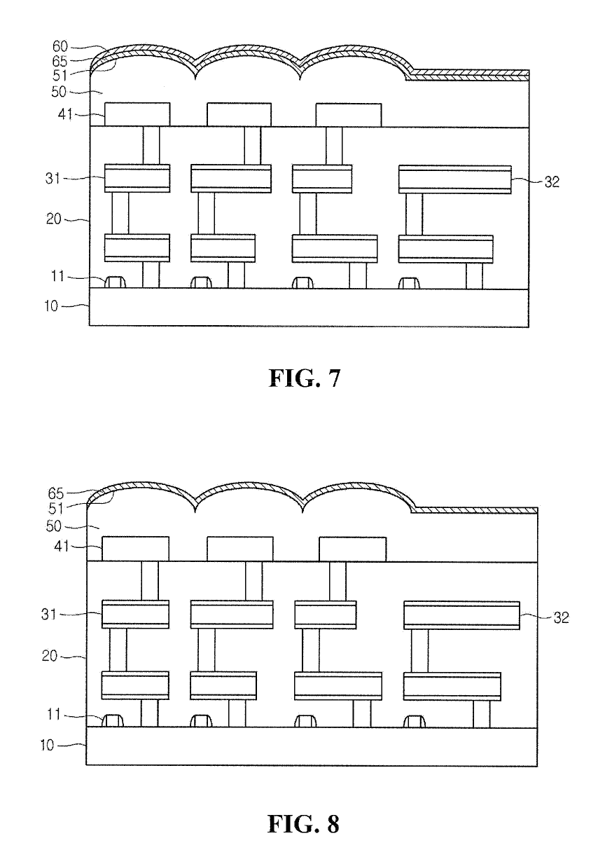

Referring to FIGS. 7 and 8, a thermal treatment process can be performed to salicide the metal layer formed on the intrinsic layer 50. For example, the thermal treatment process can be performed at a temperature of from about 200° C. to about 400° C.

The metal layer 60 in contact with a surface of the intrinsic layer 50 is salicided by the thermal process to form the salicide layer 65. In one embodiment, the salicide layer 65 can have a thickness in the range of about 50 Å to about 500 Å.

Since the salicide layer 65 has a relatively thin thickness ranging from about 50 Å to about 500 Å, the salicide layer 65 does not have a negative effect on light incident onto the intrinsic layer 50 therethrough.

During formation of the salicide layer 65, the metal layer 60 becomes salicided to remove the dangling bonds of the surface of the intrinsic layer 50 disposed therebelow.

The dangling bonds generated on the intrinsic layer 50 can be removed by forming the salicide layer 65 to inhibit the dark current of the image sensor from being generated.

Because the intrinsic layer 50 has a hemispherical shaped surface, the salicide layer 65 can also have hemispherical, or convex, shaped structure. Thus, the light incident onto the intrinsic layer 50 through the salicide layer 65 can be further condensed to improve light condensing efficiency.

Thereafter, a remaining metal material that does not react with the intrinsic layer 50 can be removed. In one embodiment, the metal layer 60 remaining on the salicide layer 65 on the intrinsic layer 50 can be removed using ceric ammonium nitrate (NH₄)₂Ce(NO₃) (CAN).

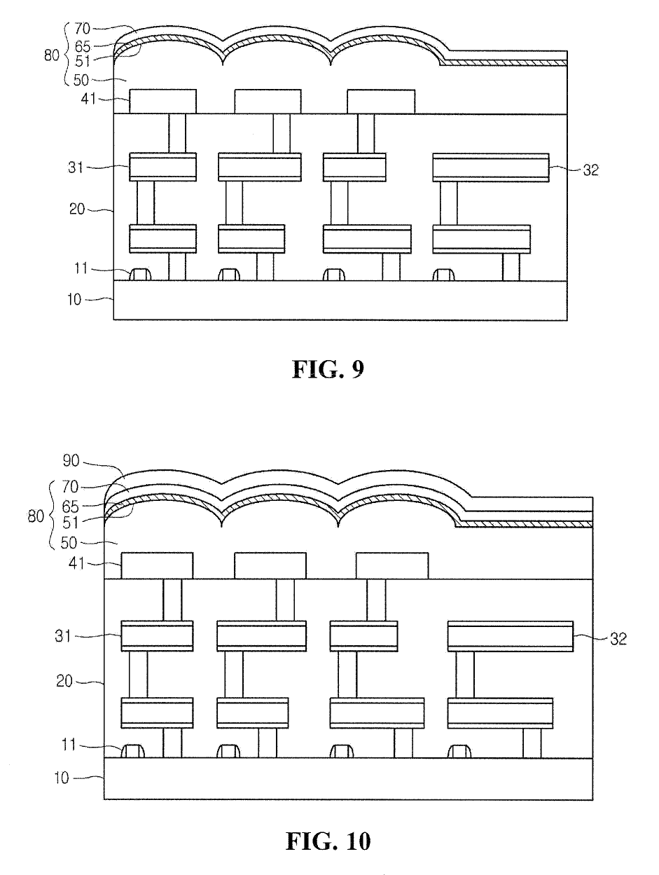

Referring to FIG. 9, a conductive type conduction layer 70 can be formed on the semiconductor substrate 10 including the intrinsic layer 50.

The conductive type conduction layer 70 can serve as a P-layer of the IP diode according to an embodiment. That is, the conductive type conduction layer 70 can include, but is not limited to, a p-type conductive type conduction layer.

In one embodiment, the conductive type conduction layer 70 can be a p-doped amorphous silicon.

The conductive type conduction layer 70 can be formed using a CVD method such as PECVD. For example, the conductive type conduction layer 70 can be formed of p-doped amorphous silicon through PECVD using SiH4 gas mixed with BH₃ or B₂H₆. In an embodiment, the conductive type conduction layer 70 can have a thickness in the range of about 50 Å to about 500 Å.

The conductive type conduction layer 70 can have a hemispherical-type shape following the shape of the intrinsic layer 50 because the conductive type conduction layer 70 is formed to a thin thickness on the intrinsic layer 50 and the salicide layer 50.

The photodiode 80 including the intrinsic layer 50 and the conductive type conduction layer 70 is vertically integrated with the CMOS circuit 11. Therefore, a fill factor of the photodiode 80 can increase to almost 100%.

Referring to FIG. 10, an upper electrode 90 can be formed on the photodiode 80.

The upper electrode 90 can include a transparent electrode having excellent light transmittance and high conductivity. For example, the upper electrode 90 can be formed of ITO, CTO, or ZnO₂.

Although not shown, a color filter and a microlens can be additionally formed on the upper electrode 90.

According to an embodiment, since the photodiode 80 is formed above the semiconductor substrate 10, the CMOS circuit 11 and the photodiode 80 can be vertically integrated, thereby increasing the fill factor to almost 100%.

The photodiode 80 and the upper electrode 90 can have a convex shape similar to the microlens to efficiently condense the incident light, thereby inhibiting the cross talk and the noise.

The salicide layer 65 can be formed on the intrinsic layer 50 of the photodiode 80 to remove dangling bonds formed during etching of the intrinsic layer 50, thereby improving image characteristics of the image sensor.

Any reference in this specification to “one embodiment,” “an embodiment,” “exemplary embodiment,” etc., means that a particular feature, structure, or characteristic described in connection with the embodiment is included in at least one embodiment of the disclosure. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with others of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An image sensor comprising:
a lower electrode on a metal interconnection electrically connected to a CMOS circuit on a semiconductor substrate;
an intrinsic layer on the lower electrode;
a salicide layer on the intrinsic layer; and
a conductive type conduction layer on the salicide layer.

2. The image sensor according to claim 1, wherein the intrinsic layer comprises a hemisphere-shaped light condensing portion.

3. The image sensor according to claim 2, wherein the salicide layer is convexly shaped according to the surface of hemisphere-shaped light condensing portion.

4. The image sensor according to claim 3, wherein the conductive type conduction layer is convexly-shaped according to a top surface of the salicide layer

5. The image sensor according to claim 1, wherein the salicide layer comprises chrome.

6. The image sensor according to claim 1, wherein the salicide layer comprises molybdenum.

7. The image sensor according to claim 1, wherein the intrinsic layer has a thickness in the range of about 2000 Å to about 20,000 Å, the salicide layer has a thickness in the range of about 100 Å to about 500 Å, and the conductive type conduction layer has a thickness in the range of about 50 Å to about 500 Å.

8. The image sensor according to claim 1, further comprising a second conductive type conduction layer on the lower electrode below the intrinsic layer.

9. The image sensor according to claim 1, further comprising an upper electrode on the conductive type conduction layer.

10. A method of manufacturing an image sensor, the method comprising:
providing a semiconductor substrate comprising:
a CMOS circuit, and
an interlayer dielectric with a metal interconnection formed therein;
forming a lower electrode on the metal interconnection;
forming an intrinsic layer on the interlayer dielectric and the lower electrode;
forming a salicide layer on the intrinsic layer; and
forming a conductive type conduction layer on the salicide layer.

11. The method according to claim 10, further comprising:
forming a seed microlens on the intrinsic layer; and
etching the intrinsic layer using the seed microlens as an etch mask to form a light condensing portion.

12. The method according to claim 11, wherein forming the seed microlens comprises:
coating the intrinsic layer with a photoresist;
patterning the photoresist to form a microlens pattern; and
performing a reflow process with respect to the microlens pattern to form the seed microlens.

13. The method according to claim 10, wherein the forming of the salicide layer comprises:
depositing a metal layer on the intrinsic layer;
thermally treating the semiconductor substrate including the metal layer to form the salicide layer; and
removing unreacted metal layer remaining on the semiconductor substrate.

14. The method according to claim 13, wherein the metal layer comprises chromium.

15. The method according to claim 13, wherein the metal layer comprises molybdenum.

16. The method according to claim 13, wherein thermally treating the semiconductor substrate comprises performing a heat treatment at a temperature between about 200° C. and about 400° C.

17. The method according to claim 13, wherein removing the unreacted metal layer comprises using ceric ammonium nitrate.

18. The method according to claim 5, wherein the intrinsic layer is formed to a thickness in the range of about 2000 Å to about 20,000 Å, the salicide layer is formed to a thickness in the range of about 100 Å to about 500 Å, and the conductive type conduction layer is formed to a thickness in the range of about 50 Å to about 500 Å.

19. The method according to claim 10, further comprising forming a second conductive type conduction layer on the lower electrode before forming the intrinsic layer.

20. The method according to claim 10, further comprising forming an upper electrode on the conductive type conduction layer.
